(19) United States
(12) Patent Application Publication
(10) Pub. No.: US 2001/0024119 A1
(43) Pub. Date: Sep. 27, 2001

(54) Robotic probe for testing printed circuit boards in-situ using a single printed circuit card slot

(75) Inventor: Brian Stockford, Bristol (GB)

Correspondence Address: PATTON BOGGS, PO BOX 270930, LOUISVILLE, CO, 80027, US

(73) Assignee: Proteus Corporation

(21) Appl. No.: 09/759,403

(22) Filed: Jan. 12, 2001

Related U.S. Application Data
(60) Provisional application No. 60/176,449, filed on Jan. 14, 2000.

(51) Int. Cl. G01R 1/00

(52) U.S. Cl. 324/158.1

(57) ABSTRACT

The in-situ robotic testing system uses a robotic probe positioning apparatus, attached to the system under test, to position the probe head and its associated probe tip at a selected location on the printed circuit board under test. Access to the printed circuit board under test is facilitated by the removal of the printed circuit board in the adjacent slot in the card cage. The robotic probe positioning apparatus comprise motors and associated control software. The control software can process user input and direct the motors to place the probe tip. The control software also directs the probe to perform the testing and provides the test results to the user. X-axis, Y-axis and Z-axis motors are used to control the linear movement of the probe head and two rotational motors control the position and orientation of the probe tip relative to the circuitry and engage the probe tip with the particular circuit trace on the printed circuit board.

### CROSS-REFERENCE TO RELATED APPLICATIONS

This application is a utility application based on and claiming priority to U.S. Provisional Application Serial No. 60/176,449, filed Jan. 14, 2000.

### FIELD OF THE INVENTION

The present robotic probe system pertains to the field of printed circuit board testing and, in particular, to testing the circuitry on a printed circuit board while the printed circuit board is mounted in a system under test, via the use of robotics to position a probe.

### PROBLEM

It is a problem in the field of printed circuit board testing to test a printed circuit board while installed in the system under test. A typical printed circuit board based system (system under test) includes a card cage that is equipped with a plurality of slots, each of which has a connector for interfacing a printed circuit board with backplane wiring. The printed circuit boards are inserted into their assigned slots and the system under test is then operational to perform its designated functions. In this environment, it is not uncommon for some of these printed circuit boards to operate in close cooperation with other printed circuit boards in the system under test. Therefore, the testing of these printed circuit boards must be in-situ and requires that the printed circuit board testing be accomplished via access to the backplane wiring. This is due to the fact that when all of these printed circuit boards are mounted in their assigned slots in a card cage, there is insufficient room to access the surface of the printed circuit boards due to the close spacing of the printed circuit boards in the card cage. In addition, complex circuitry on printed circuit boards typically has minimal spacing between the various circuits and components resident on the printed circuit board. However, access to the backplane wiring limits the amount of testing that can be accomplished, due to the extensive amount of signal processing that occurs on each printed circuit board. Therefore, in this situation, effective in-situ testing of printed circuit boards is impossible and the printed circuit boards must be removed from the system under test to be tested in isolation from the other printed circuit boards in the system under test. This process limits the effectiveness of the testing, since the close cooperation between the printed circuit board under test and the other printed circuit boards in the system under test is lost.

The present state of the art in printed circuit board testing is that complex printed circuit boards are typically tested by manually placing a probe tip at a predefined point on the printed circuit board to assess the signal integrity or to inject a fault into the circuit. The high density of circuitry on a printed circuit board poses a major challenge to manual testing. High circuit density may require the test engineers to use microscopes to manually place the probe tip on the printed circuit board. Small pins may need to be soldered to the probe tip for finer precision placement on the printed circuit board. There is little room for error when placing the probe tip in this environment. Awkward mechanical probe holders are often required to ensure that the probe tip does not move from the test point once it is so painstakingly positioned. Despite such efforts, printed circuit board test results often contain errors due to probe tip misalignment.

The high-speed operation of modern circuitry causes additional problems. High operating frequencies impose tight restrictions on test equipment because high frequency signals degrade quickly when transmitted over the probe tip and the probe leads that interconnect the probe tip to the test equipment due to the impedance of this signal path. The present manual testing techniques typically require long probe tips and probe leads that can cause severe signal degradation. Manual testing also requires that trained engineers be present to perform the tests. This requirement drives up the cost of the testing. It also hinders the effective use of remote testing because test engineers must be on-site with the test equipment. The test engineers cannot direct placement of the probe tip and view test results from a remote location. Manual testing techniques are costly, time-consuming, and error-prone given the complexity of modern circuitry. There is a distinct need for a testing system that is automated, fast, accurate, and cost-effective.

Automated testing has been used to address a number of the above-noted problems encountered with manual testing. The automated testing systems, such as is disclosed in PCT Patent Application PCT/US99/31236, published as International Publication Number WO 00/39595, utilizes radial arm robotics to place a probe tip at selected points on a printed circuit board with extreme precision. The robotic placement of twin probe tips on the circuitry allows the associated probe leads to be as short as possible and minimizes the impedance and inductance associated with the probe leads. System reliability is enhanced by the rotational/radial positioning of the probe tips, as opposed to X-Y positioning, because the bobbin leads fatigue less and last longer under repetitive motion strain. The robotics used in this system comprise precision DC motors and associated control software. The control software can process user input and direct the motors to place the probe tips at a selected location with a high degree of precision and repeatability. The control software also directs the probe to perform the testing and provides the test results to the user. This automated testing system also provides for remote testing of printed circuit boards. A remote terminal is used to display a diagram of the circuitry to the user. The user may then simply point and click on the remote terminal display to identify both probe placement points and selected tests to be executed by the automated testing system. In response to these user inputs, control software directs the motors to position the probe tips relative to one another and to the printed circuit board. The control software then directs the probe to conduct the user-selected tests. Finally, the control software displays the test results to the user at the remote terminal display for evaluation and activation of further tests.

However, none of the above-noted printed circuit board testing systems address the need for in-situ testing of printed circuit boards. There is a need for a printed circuit board testing system that can access the surface of the printed circuit board while the printed circuit board is operational in the system under test to perform fault injection, signal measurement, and other such test operations. This system should be automated to enable precision placement of the probe tip on the surface of the printed circuit board.

### SOLUTION

The above-described problems have been solved and a technical advance achieved by the present robotic system for testing printed circuit boards in-situ, using a single printed circuit board slot (termed the “in-situ robotic testing system” herein). The in-situ robotic testing system performs testing quickly and accurately on the printed circuit boards while they are operational in the system under test, and allows remote testing of the printed circuit boards.

The in-situ robotic testing system uses a robotic probe positioning apparatus, attached to the system under test, to position the probe head and its associated probe tip at a selected location on the printed circuit board under test. Access to the printed circuit board under test is facilitated by the removal of the printed circuit board in the adjacent slot in the card cage. The robotic probe positioning apparatus comprise precision DC motors and associated control software. The control software can process user input and direct the motors to place the probe tip at a selected location on the printed circuit board. The control software also directs the probe to perform the testing and provides the test results to the user. X-axis, Y-axis and Z-axis motors are used to control the linear movement of the probe head in three linear axes of movement, two rotational motors control the position and orientation of the probe tip relative to the circuitry in polar coordinate axes of movement and also engage the probe tip with the particular circuit trace on the printed circuit board.

The in-situ robotic testing system also provides for remote testing of printed circuit boards. A remote terminal is used to display a diagram of the circuitry mounted on the printed circuit board to the user. The user may then simply point and click on the remote terminal display to identify both probe placement points and selected tests to be executed by the automated testing system. In response to these user inputs, control software directs the motors to position the probe tips relative to one another and to the printed circuit board. The control software then directs the probe to conduct the user-selected tests. Finally, the control software displays the test results to the user at the remote terminal display for evaluation and execution of further tests.

The in-situ robotic testing system performs automated testing of complex circuitry by placing the probe tip at a selected probe placement point with extreme precision. The probe tip is placed with a resolution of 0.00254 cm (0.001 inches) of the selected probe tip placement point. Automation also allows the testing to be performed quickly and accurately without the problems associated with manual testing.

### BRIEF DESCRIPTION OF THE DRAWING

FIGS. 1 & 2 illustrate top plan and perspective views, respectively, of the in-situ robotic testing system; and

FIGS. 3 & 4 illustrate bottom plan and side plan views of the probe head used in the in-situ robotic testing system.

### DETAILED DESCRIPTION OF THE DRAWING

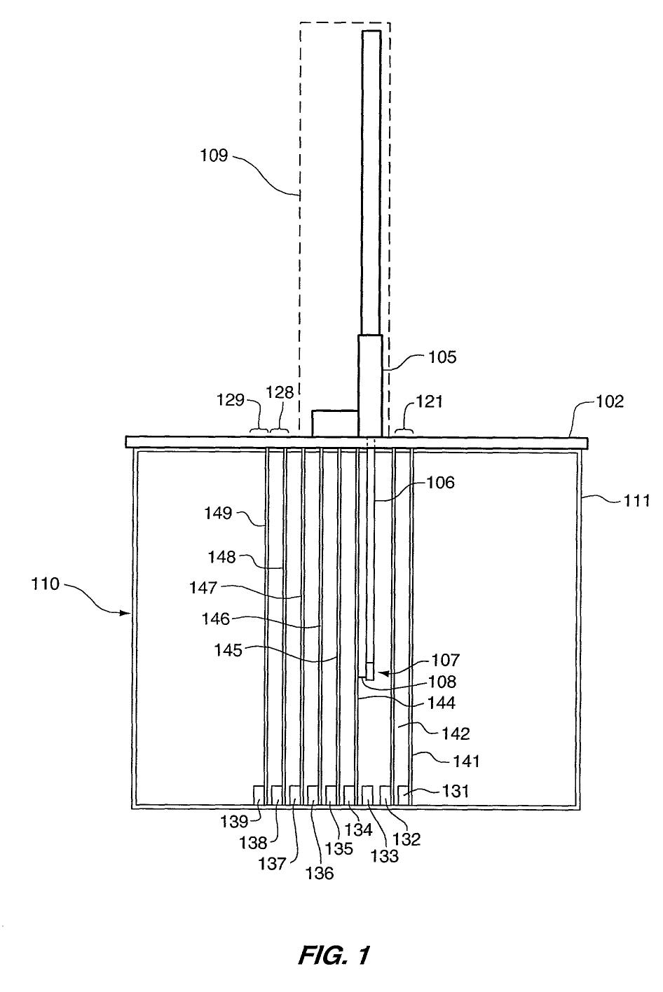

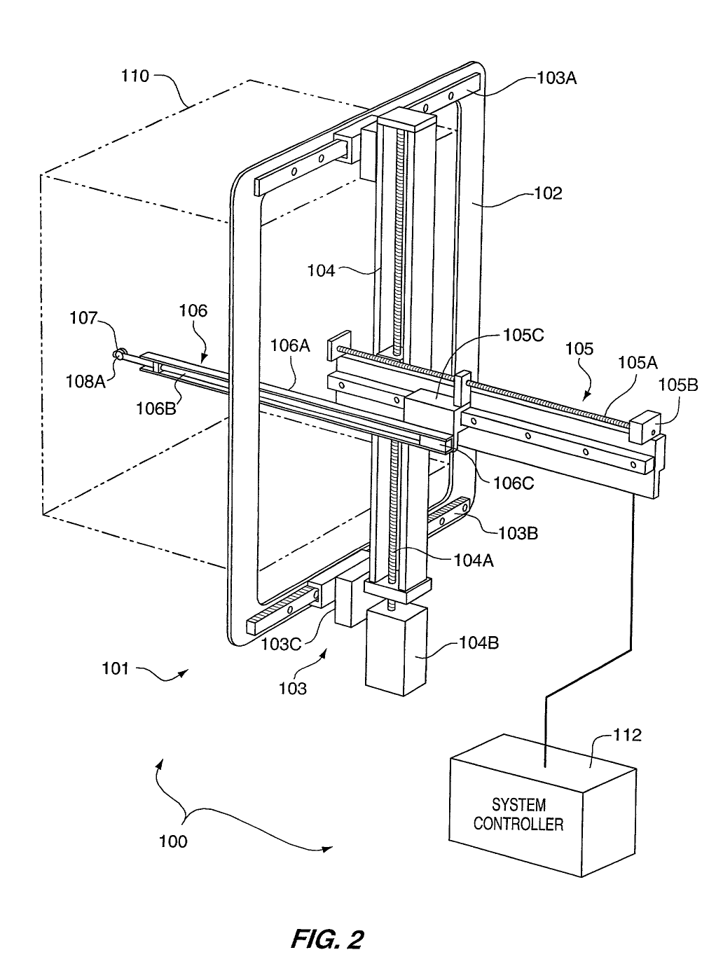

As shown in FIGS. 1, and 2, a typical printed circuit board based system (system under test 110) includes a card cage 111 that is equipped with a plurality of slots 121-129, each of which has a connector 131-139 for interfacing a printed circuit board 141-149 with backplane wiring (not shown). The printed circuit boards 141-149 are inserted into their assigned slots 131-139 and the system under test 110 is then operational to perform its designated functions. In this environment, it is not uncommon for some of these printed circuit boards to operate in close cooperation with other printed circuit boards in the system under test 110. For example, the circuitry used to implement a particular subsystem may reside on two printed circuit boards, without there being a simple signal interface between the two boards. Therefore, the testing of these printed circuit boards must be in-situ and requires that the printed circuit board testing be accomplished via access to the backplane wiring. This is due to the fact that when all of these printed circuit boards are mounted in their assigned slots in a card cage, there is insufficient room to access the surface of the printed circuit boards due to the close spacing of the printed circuit boards in the card cage. In addition, complex circuitry on printed circuit boards typically has minimal spacing between the various circuits and components resident on the printed circuit board.

### Robotic Probe Positioning Apparatus

FIG. 1 illustrates a top plan view and FIG. 2 illustrates a perspective view, respectively, of the in-situ robotic testing system 100 as it is connected to the system under test 110. In the example used herein, the surface of the circuitry mounted on the printed circuit boards 141-149 lies in the X-Y plane of a Cartesian reference system and in the rotational/radial plane of a polar reference system. The surface of the circuitry is perpendicular to the Z-axis of both reference systems.

The in-situ robotic testing system 100 is connected to the system under test 110 by affixing it to the card cage 111 of the system under test 110. For the purpose of accuracy, the robotic assembly 101 of the in-situ robotic testing system 100 is attached to the system under test 110 using a dedicated precision interface, that includes frame 102. The card cage 111 is used to mount the robotic assembly 101 by attaching frame 102 to the open face of the card cage 111. The robotic assembly 101 consists of an X-axis positioning apparatus 103 which controls the X-axis position of an Y-axis positioning mechanism 104, which controls the Y-axis position of the Z-axis positioning mechanism 105 to control the location of the probe arm 106. The probe arm 106 is equipped with a probe head 107, located on the end of the probe arm 106 distal from a carriage apparatus 105C that is part of the Z-axis positioning mechanism 105. The probe head 107 is equipped with a probe tip 108, as is described below. A protective shield 109 can be used to protect the robotic assembly 101 from the user and any other potential sources of interference.

This robotic assembly 101 typically provides access to the trace side of the printed circuit boards 141-149. This is accomplished by removing the printed circuit board adjacent to the selected printed circuit board 144 that is under test to provide probe head 107 with access to the trace side 144T of the selected printed circuit board 144. The robotic assembly 101 thereby provides 5-axis motion control of the probe head 107 and associated probe tip 108 in the space (slot 123) vacated by the removed printed circuit board, which is the space between the printed circuit board under test 144 and the next adjacent printed circuit board 142. There are three Cartesian coordinate axes and two polar coordinate axes for the robotic apparatus 101. The basic robotic positioning framework is a substantially rectangular high-speed Cartesian coordinate positioning system. There is an XY-axis movement implemented by this XY-axis positioning apparatus 103, 104 to position the probe arm 106 in the proper position, located opposite the selected vacated printed circuit board slot 123. The Z-axis movement is implemented by the Z-axis positioning mechanism 105 which controls the range of movement of the probe arm 106 in a Z-axis direction in the vacated printed circuit board slot 123. The probe arm 106 itself has rotational polar coordinate movement with respect to the carriage apparatus 105C and the probe head 107 also has rotational polar coordinate movement with respect to the probe arm 106.

For the X-axis movement, guide rails 103A, 103B and linear actuator 103C are used in a traditional configuration to support and move the Y-axis positioning mechanism 104. For the Y-axis movement, guide rail 104A and linear actuator 104B are used in a traditional configuration to support and move the Z-axis positioning mechanism 105. For the Z-axis movement, guide rail 105A and linear actuator 105B are used in a traditional configuration to support and move the carriage 105C that holds the probe arm 106. The probe arm 106 itself consists of a support frame 106A and a rotatable shaft 106B, which rotatable shaft 106B can be moved in a polar coordinate reference frame with respect to carriage 105C by rotational motor 106C to control the positioning of the probe head 107. The support frame 106A provides stability and support to the rotatable shaft 106B, thereby improving the precision of placement on the probe tip 108. The probe head 107 itself consists of a probe tip 108 and associated rotational motor 108A that serves to position the probe tip 108 with respect to a selected trace on the printed circuit board under test 144.

The use of guide rails is preferred over a ground shaft and linear bearing type of assembly because of its higher mechanical performance: higher rigidity, higher load bearing capacity, and self-aligning capability. The linear actuators 103C, 104B, 105B provide reliable precision translation and low frictional resistance. The linear actuators consist of drive motors that can be implemented using DC brushed servomotors that drive the X-axis, Y-axis and Z-axis movements. Non-contact differential linear encoders provide positional feedback for the X-axis and Y-axis movement. High-resolution differential rotary encoders provide feedback on the Z-axis and the polar axes. Backlash eliminators are fitted to the X-axis and Y-axis apparatus to ensure positional repeatability and long maintenance intervals for the robotic apparatus 101. Rotational motors 106C, 108A provide precise positioning of the probe tip 108 by controlling movement in the above-noted two polar coordinate axes.

The X-axis, Y-axis positioning apparatus 103, 104 described above is a conventional configuration known to those skilled in the art. The high-resolution differential rotary encoders control the action of their associated drive motors in response to control signals from a system controller 112. Those skilled in the art appreciate that the high-resolution differential rotary encoders could be incorporated into their respective drive motors.

The system controller 112 generates and provides control signals in response to user input, as is described for the analogous X-axis, Y-axis robotic positioning apparatus in the above noted PCT Patent Application PCT/US99/31236. The control signals cause the X-axis, Y-axis, Z-axis positioning apparatus 103, 104, 105 to position the probe head 107 relative to the printed circuit board under test 144. The control signals generated by the system controller 112 to also cause the rotational motors 106C, 108A to properly position the probe tip 108 relative to the printed circuit board under test 144 and to engage the probe tip 108 with a selected trace on the printed circuit board under test 144.

### Probe Assembly

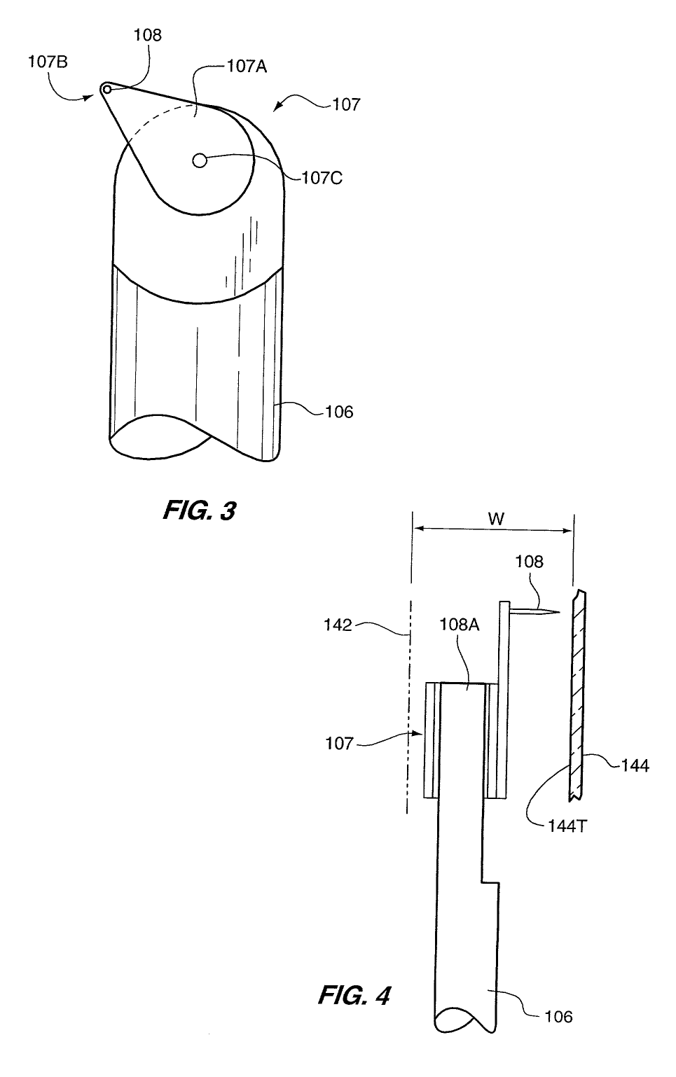

The probe head 107, as shown in FIGS. 3 & 4, is implemented as an eccentric shaped cam 107A, pivotally connected to the probe arm 106. This enables the probe tip 108, mounted at the narrow end 107B of the eccentric shaped cam 107A distal from the pivot 107C, to reach beyond the extent of the probe arm 107, as shown in these Figures. The rotation of the probe tip 108 is controlled by the rotational motor 108A, that serves to position the probe tip 108 in a polar coordinate axis, centered at the pivot 107B in response to control signals received from system controller 112. The probe head 107 typically incorporates circuitry for testing the printed circuit board, such as fault injection electronics (not shown). There typically is an integrated (fixed length) signal lead to reduce inductance. Due to the narrow width W of the printed circuit board slot opening, the probe tip 108 is of a stylus type. The probe, in a typical application, injects faults into the traces on the printed circuit board under test 144 and uses an external ground connection from the in-situ robotic testing system 100 to the system under test 110 to complete the circuit. The probe head 107 can rotate clear of the end of the probe arm 106 to extend the test coverage area. The probe head 107 has a compact footprint to provide the maximum working envelope. There are a minimum of moving parts and highly repeatable probe tip positioning.

Probe head 107 and associated probe tip 108 could comprise any device that is capable of testing circuitry. Some examples of such probes are active FET probes, differential probes, time domain reflectrometry probes, RF probes, and shorting probes. The probe tip 108 and the associated probe leads should remain as short as possible to minimize inductance and capacitance.

### Summary

The in-situ robotic testing system uses a robotic probe positioning apparatus, attached to the system under test, to position the probe head and its associated probe tip at a selected location on the printed circuit board under test. Access to the printed circuit board under test is facilitated by the removal of the printed circuit board in the adjacent slot in the card cage.

What is claimed is:

1. An in-situ robotic testing system for testing circuitry contained on a selected printed circuit board that is mounted, along with other printed circuit boards, in a card cage in a system under test, comprising:
mounting means for connecting said in-situ robotic testing system to said system under test to enable access to said printed circuit boards that are located in said card cage;
probe head means, including a probe tip means mounted thereon, for electrically interconnecting said in-situ robotic testing system to electrical conductors on said selected printed circuit board;
probe arm means having a distal end on which said probe head means is mounted for placing said probe tip means in electrical contact with said electrical conductors on said selected printed circuit board;
probe arm positioning means for positioning said probe arm means opposite a selected printed circuit board slot that is located adjacent said selected printed circuit board and from which selected printed circuit board slot the printed circuit board is removed; and
probe head positioning means for positioning said probe head means mounted on a distal end of said probe arm means in said selected printed circuit board slot and above a selected location on said selected printed circuit board to place said probe tip means in electrical contact with said electrical conductors on said selected printed circuit board.

2. The in-situ robotic testing system of claim 1 wherein said means for mounting comprises:
frame means connectable to said card cage for precisely aligning said in-situ robotic testing system opposite an open side of said card cage.

3. The in-situ robotic testing system of claim 2 wherein said probe arm positioning means comprises:
carriage means for transporting said probe arm;
X-axis positioning means, connected to said frame means, and operable to move said carriage means in an X-axis direction with respect to said card cage;
Y-axis positioning means, connected to said X-axis positioning means, and operable to move said carriage means in an Y-axis direction with respect to said card cage.

4. The in-situ robotic testing system of claim 3 wherein said X-axis positioning means comprises:
X-axis rail means for providing a path over which said Y-axis positioning means can traverse in the X-axis direction; and
X-axis motor means for propelling said Y-axis positioning means along said X-axis rail means.

5. The in-situ robotic testing system of claim 4 wherein said Y-axis positioning means comprises:
Y-axis rail means for providing a path over which said carriage means can traverse in the Y-axis direction; and
Y-axis motor means for propelling said carriage means along said Y-axis rail means.

6. The in-situ robotic testing system of claim 3 wherein said probe head positioning means comprises:
Z-axis positioning means, connected to said carriage means, and operable to move said probe arm means in the Z-axis direction with respect to said card cage.

7. The in-situ robotic testing system of claim 6 wherein said Z-axis positioning means comprises:
Z-axis rail means for providing a path over which said probe arm means can traverse in the Z-axis direction; and
Z-axis motor means for propelling said probe arm means along said Z-axis rail means.

8. The in-situ robotic testing system of claim 7 further comprising:
motion control means for generating control signals to controllably activate said X-axis motor means to propel said Y-axis positioning means along said X-axis rail means, said Y-axis motor means to propel said carriage means along said Y-axis rail means, and said Z-axis motor means to propel said probe arm means along said Z-axis rail means.

9. The in-situ robotic testing system of claim 1 further comprising:
test means, responsive to said probe tip means being placed in electrical contact with said electrical conductors on said selected printed circuit board, for exchanging signals with said selected printed circuit board via said probe tip means.

10. The in-situ robotic testing system of claim 1 wherein said probe head positioning means comprises:
probe arm rotation means for controllably rotating said probe arm means with respect to said selected printed circuit board.

11. The in-situ robotic testing system of claim 10 wherein said probe head positioning means further comprises:
probe tip rotation means for controllably rotating said probe tip means about a rotational axis with respect to said probe head means to place said probe tip means in electrical contact with said electrical conductors on said selected printed circuit board.

12. A method of testing printed circuit boards using an in-situ robotic testing system for testing circuitry contained on a selected printed circuit board that is mounted, along with other printed circuit boards, in a card cage in a system under test, wherein said in-situ robotic testing system includes a probe head, including a probe tip mounted thereon, for electrically interconnecting said in-situ robotic testing system to electrical conductors on said selected printed circuit board and a probe arm having a distal end on which said probe head is mounted for placing said probe tip in electrical contact with said electrical conductors on said selected printed circuit board, said method comprising the steps of:
connecting said in-situ robotic testing system to said system under test to enable access to said printed circuit boards that are located in said card cage;
positioning said probe arm opposite a selected printed circuit board slot that is located adjacent said selected printed circuit board and from which selected printed circuit board slot the printed circuit board is removed; and
positioning said probe head mounted on a distal end of said probe arm in said selected printed circuit board slot and above a selected location on said selected printed circuit board to place said probe tip in electrical contact with said electrical conductors on said selected printed circuit board.

13. The method of testing printed circuit boards using an in-situ robotic testing system of claim 12 wherein said step of mounting comprises:
connecting a frame to said card cage for precisely aligning said in-situ robotic testing system opposite an open side of said card cage.

14. The method of testing printed circuit boards using an in-situ robotic testing system of claim 13 wherein said step of probe arm positioning comprises:
mounting said probe arm on a carriage;
operating an X-axis positioning apparatus, connected to said frame, and operable to move said carriage in an X-axis direction with respect to said card cage;
operating an Y-axis positioning apparatus, connected to said X-axis positioning apparatus, and operable to move said carriage in an Y-axis direction with respect to said card cage.

15. The method of testing printed circuit boards using an in-situ robotic testing system of claim 14 wherein said step of operating said X-axis positioning apparatus comprises:
providing an X-axis path over which said Y-axis positioning apparatus can traverse in the X-axis direction; and
propelling said Y-axis positioning apparatus along said X-axis path.

16. The method of testing printed circuit boards using an in-situ robotic testing system of claim 15 wherein said step of operating said Y-axis positioning apparatus comprises:
providing an Y-axis path over which said carriage can traverse in the Y-axis direction; and
propelling said carriage along said Y-axis path.

17. The method of testing printed circuit boards using an in-situ robotic testing system of claim 14 wherein said step of positioning said probe head comprises:
operating an Z-axis positioning apparatus, connected to said carriage, to move said probe arm in the Z-axis direction with respect to said card cage.

18. The method of testing printed circuit boards using an in-situ robotic testing system of claim 17 wherein said step of operating an Z-axis positioning apparatus comprises:
providing an Z-axis path over which said probe arm can traverse in the Z-axis direction; and
propelling said probe arm along said Z-axis path.

19. The method of testing printed circuit boards using an in-situ robotic testing system of claim 18 further comprising the step of:
generating motion control signals to controllably propel said Y-axis positioning apparatus along said X-axis path, controllably propel said carriage along said Y-axis path, and controllably propel said probe arm along said Z-axis rail path.

20. The method of testing printed circuit boards using an in-situ robotic testing system of claim 12 further comprising the step of:
exchanging, in response to said probe tip being placed in electrical contact with said electrical conductors on said selected printed circuit board, signals with said selected printed circuit board via said probe tip.

21. The method of testing printed circuit boards using an in-situ robotic testing system of claim 12 wherein said step of positioning said probe head comprises:
controllably rotating said probe arm with respect to said selected printed circuit board.

22. The method of testing printed circuit boards using an in-situ robotic testing system of claim 21 wherein said step of positioning said probe head further comprises:
controllably rotating said probe tip about a rotational axis with respect to said probe head to place said probe tip in electrical contact with said electrical conductors on said selected printed circuit board.
